(19) United States
(12) Patent Application Publication
(10) Pub. No.: US 2013/0302974 A1
(43) Pub. Date: Nov. 14, 2013

(54) REPLACEMENT GATE ELECTRODE FILL AT REDUCED TEMPERATURES

(71) Applicants: Jens Hahn, Dresden (DE); Torsten Huisinga, Dresden (DE); Klaus Hempel, Dresden (DE); Oisin Kenny, Dresden (DE)

(72) Inventors: Jens Hahn, Dresden (DE); Torsten Huisinga, Dresden (DE); Klaus Hempel, Dresden (DE); Oisin Kenny, Dresden (DE)

(73) Assignee: GLOBALFOUNDRIES INC., Grand Cayman (KY)

(21) Appl. No.: 13/466,247

(22) Filed: May 8, 2012

(51) Int. Cl. H01L 21/283

(52) U.S. Cl. 438/585; 257/E21.19

(57) ABSTRACT

Generally, the present disclosure is directed to forming conductive metal fill materials in replacement gate electrodes using reduced deposition temperatures. One illustrative method disclosed herein includes, among other things, forming a sacrificial gate structure above a semiconductor layer, the sacrificial gate structure including a dummy gate electrode, and forming a gate cavity by removing at least the dummy gate electrode from above the semiconductor layer. The disclosed method further includes forming a work-function material of a replacement metal gate electrode in the gate cavity, and forming a conductive metal fill material in the gate cavity and above the work-function material, wherein forming the conductive metal fill material includes performing a material deposition process at a temperature below approximately 450° C.

### BACKGROUND OF THE INVENTION

1. Field of the Invention

Generally, the present invention relates to sophisticated integrated circuits, and, more particularly, to forming a conductive metal fill material in replacement gate electrodes at reduced temperatures.

2. Description of the Related Art

The fabrication of advanced integrated circuits, such as CPU's, storage devices, ASIC's (application specific integrated circuits) and the like, requires the formation of a large number of circuit elements on a given chip area according to a specified circuit layout, wherein field effect transistors represent one important type of circuit elements that substantially determine performance of the integrated circuits. Generally, a plurality of process technologies are currently practiced, wherein, for many types of complex circuitry, including field effect transistors, MOS technology is currently one of the most promising approaches due to the superior characteristics in view of operating speed and/or power consumption and/or cost efficiency. During the fabrication of complex integrated circuits using, for instance, MOS technology, millions of transistors, e.g., N-channel transistors and/or P-channel transistors, are formed on a substrate including a crystalline semiconductor layer. A field effect transistor, irrespective of whether an N-channel transistor or a P-channel transistor is considered, typically comprises so-called PN junctions that are formed by an interface of highly doped regions, referred to as drain and source regions, with a slightly doped or non-doped region, such as a channel region, disposed adjacent to the highly doped regions.

In a field effect transistor, the conductivity of the channel region, i.e., the drive current capability of the conductive channel, is controlled by a gate electrode formed adjacent to the channel region and separated therefrom by a thin insulating layer. The conductivity of the channel region, upon formation of a conductive channel due to the application of an appropriate control voltage to the gate electrode, depends on the dopant concentration, the mobility of the charge carriers and, for a given extension of the channel region in the transistor width direction, on the distance between the source and drain regions, which is also referred to as channel length. Hence, in combination with the capability of rapidly creating a conductive channel below the insulating layer upon application of the control voltage to the gate electrode, the conductivity of the channel region substantially affects the performance of MOS transistors. Thus, as the speed of creating the channel, which depends on the conductivity of the gate electrode, and the channel resistivity substantially determine the transistor characteristics, the scaling of the channel length, and associated therewith the reduction of channel resistivity and increase of gate resistivity, is a dominant design criterion for accomplishing an increase in the operating speed of the integrated circuits.

For many device technology generations, the gate structures of most transistor elements has generally been made up of silicon and/or silicon-based materials, such as a polysilicon gate electrode in combination with a silicon dioxide and/or silicon oxynitride gate dielectric layer, sometimes referred to as a “polySiON” gate configuration. However, as the channel length of aggressively scaled transistor elements has become increasingly smaller, many newer generation devices have turned to gate stacks comprising alternative materials in an effort to avoid the short-channel effects which may be associated with the use of traditional silicon-based materials in reduced channel length transistors. For example, in some aggressively scaled transistor elements, which sometimes have channel lengths on the order of 14-32 nm or even shorter, gate stacks made up of a so-called high-k dielectric/metal gate (HK/MG) configuration have been shown to provide significantly enhanced operational characteristics over the heretofore more commonly used polySiON gate configurations.

In many conventional high-k dielectric/metal gate transistor applications, the HK/MG gate structures are formed using the so-called “gate last” or “replacement gate” technique, wherein a sacrificial gate structure based on polySiON gate architecture is initially formed so as to facilitate formation of various transistor elements, such as sidewall spacer structures, source/drain regions, silicide contact regions, and the like. The sacrificial gate structure, which can include a “dummy” polysilicon gate electrode and a “dummy” silicon dioxide/oxynitride gate dielectric layer, is then selectively removed to form a gate cavity, and the “replacement” HK/MG gate structure is formed in the gate cavity.

Typically, an HK/MG gate structure is formed by depositing one or more metal gate electrode “work-function” material layers above a high-k dielectric layer, which may be made up of one or more high-k dielectric materials, i.e., materials having a dielectric constant of approximately 10 or higher. Depending on the specific conductivity type of the transistor element being formed, e.g., a PMOS or an NMOS transistor, the material types, thicknesses, and arrangement of the one or more work-function material layers may be adjusted as required so as to provide the desired work-function of the HK/MG transistor element. Thereafter, once all of the required work-function material layers have been formed in the gate cavity, a final material deposition operation is performed so as to fill the remaining portion of the gate cavity with conductive metal so as to complete the HK/MG gate structure. In many applications, the conductive metal fill is generally aluminum, which is typically deposited in the remaining portion of the gate cavity using a well-known physical vapor deposition (PVD) process, and the like.

As HK/MG transistor element are more aggressively scaled, the final conductive metal fill operation may sometimes become problematic, due to the substantially reduced critical dimension of the remaining portion of the gate cavity that is filled during this operation. For example, in highly scaled devices, such as those based on the 20-22 nm design node, the critical dimension—i.e., the width—of the remaining portion of the gate cavity may be in the range of 12-16 nm, or even smaller. With such exceedingly small critical dimensions, it can sometimes be difficult to fill the reduced-size gate cavity without creating voids in the conductive metal fill—a situation which can have a significant impact on the overall device performance. Accordingly, the material deposition process that is used to deposit a conductive metal fill material, such as aluminum, in gate cavities having critical dimensions of such reduced size is typically performed at temperatures that are sufficiently high so as to allow the conductive metal fill to readily “flow” into the cavity, thus reducing the likelihood that voids may be formed or trapped during the deposition process.

For example, when a PVD process is used to form an aluminum fill in a reduced-size gate cavity, it will generally be performed in the range of between 450° C. and 500° C., i.e., a temperature where the aluminum will readily “flow” into the cavity. Furthermore, the higher deposition temperatures also provide a recrystallized grain structure of the conductive metal fill material, such that larger grain sizes are produced, thereby providing an enhanced electrical performance of the conductive metal fill.

However, there may also be some unwanted consequences with respect to the overall performance of HK/MG devices as a result of using such elevated temperatures to form the conductive metal fill material. For example, the increased thermal budget of the device resulting from an elevated material deposition temperature, such as when a PVD deposition process is performed in excess of 450° C., may lead to an uncontrolled and undesirable shift in the device work function. Additionally, when the work-function layers are initially deposited in such a way as to induce stresses in the channel region of the device, the intrinsic stresses present in the work-function layers may be reduced to an unquantifiable degree due to the higher deposition temperature and consequent increased thermal budget. Both of these factors can have a substantial detrimental effect on the device switching speed and overall performance.

Furthermore, when the conductive metal fill material is aluminum, the likelihood that aluminum spiking, or junction spiking, may occur substantially increases with higher material deposition temperatures. During aluminum spiking, the aluminum material present in the metal gate electrode may tend to diffuse into the silicon-based material of the channel region below the gate structure, which may thereby lead to an increase in device leakage current. This effect is generally greater in NMOS HK/MG devices, due to the fact that a fewer number of work-function material layers may be present between the conductive metal fill material, i.e., the aluminum fill, and the gate dielectric layer, as compared to that of corresponding PMOS devices.

The present disclosure is directed to various approaches for forming conductive metal fill materials in replacement metal gate electrodes that may avoid, or at least reduce, the effects of one or more of the problems identified above.

### SUMMARY OF THE DISCLOSURE

The following presents a simplified summary of the present disclosure in order to provide a basic understanding of some aspects disclosed herein. This summary is not an exhaustive overview of the disclosure, nor is it intended to identify key or critical elements of the subject matter disclosed here. Its sole purpose is to present some concepts in a simplified form as a prelude to the more detailed description that is discussed later.

Generally, the present disclosure is directed to forming conductive metal fill materials in replacement gate electrodes using reduced deposition temperatures. One illustrative method disclosed herein includes, among other things, forming a sacrificial gate structure above a semiconductor layer, the sacrificial gate structure including a dummy gate electrode, and forming a gate cavity by removing at least the dummy gate electrode from above the semiconductor layer. The disclosed method further includes forming a work-function material of a replacement metal gate electrode in the gate cavity, and forming a conductive metal fill material in the gate cavity and above the work-function material, wherein forming the conductive metal fill material includes performing a material deposition process at a temperature below approximately 450° C.

In another illustrative embodiment of the present disclosure is a method for forming a replacement gate structure of a semiconductor device that includes forming a sacrificial gate structure above a semiconductor layer of the semiconductor device, and forming a gate cavity by selectively removing the sacrificial gate structure from above the semiconductor layer. Furthermore, the method also includes, among other things, partially filling the gate cavity by forming at least one layer of a metal gate electrode work-function material in the gate cavity, and filling a remaining portion of the gate cavity with a conductive metal fill material by performing a physical vapor deposition process at a temperature below approximately 450° C.

Also disclosed herein is an illustrative method for forming a replacement gate electrode that includes, among other things, forming at least one work-function material layer in a gate cavity, wherein the at least one work-function material layer is formed above a gate dielectric layer and adjacent to sidewalls of said gate cavity. Additionally, the disclosed method further includes performing an electrochemical deposition process at a temperature of approximately 50° C. or less so as to form a conductive metal fill material above the at least one work-function material layer, the conductive metal fill material completely filling a remaining portion of the gate cavity.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1b graphically depict representative performance improvement metrics of certain demonstrative transistor elements that have been formed using at least some of the illustrative manufacturing steps disclosed herein; and

FIGS. 2a-2f schematically depict various steps of an illustrative method that may be used to form conductive metal fill materials in replacement metal gate electrodes.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the present subject matter are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the subject matter of the present disclosure is directed to various methods for forming conductive metal fill materials in replacement gate electrodes using reduced deposition temperatures. In certain illustrative embodiments, a physical vapor deposition (PVD) process may be performed at a temperature below approximately 450° C. so as to form a conductive metal fill material in a replacement metal gate electrode. For example, the PVD process used to form the conductive metal fill material in the replacement metal gate electrode may be performed in the range of approximately 400° C. to 420° C., whereas in other embodiments, the PVD process deposition temperature may be less than 400° C. Additionally, at least some device performance parameters may be significantly increased, as noted below, in embodiments of the present disclosure wherein the maximum temperature of subsequently performed processes does not substantially exceed the temperature at which the conductive metal fill material is formed in the replacement metal gate electrode. Furthermore, in certain embodiments, the conductive metal fill material may be, for example, an aluminum-germanium (AlGe) alloy fill material, whereas in at least some embodiments, the germanium content of the AlGe alloy fill material may be approximately 5% atomic weight or less.

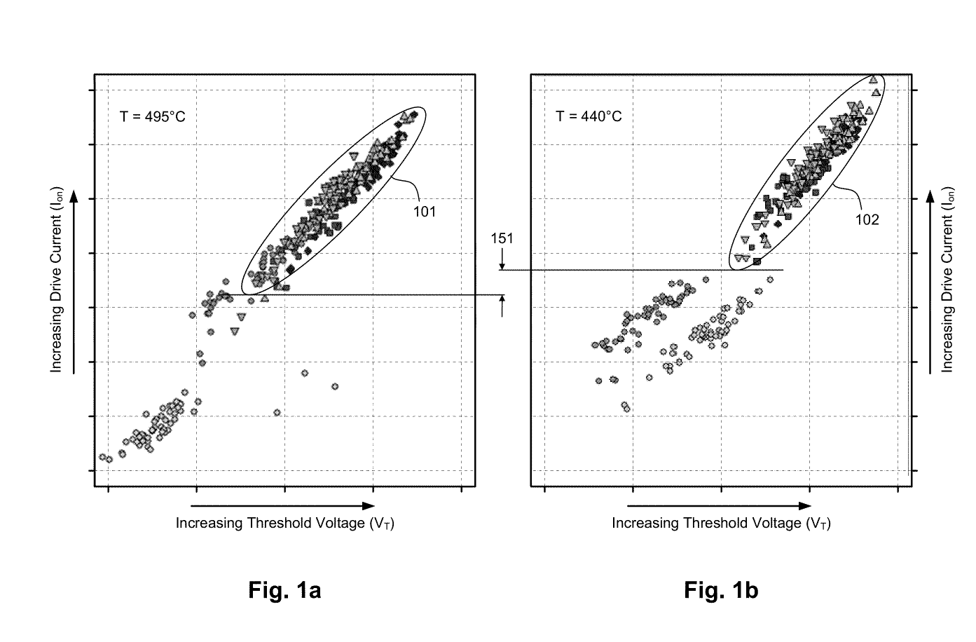

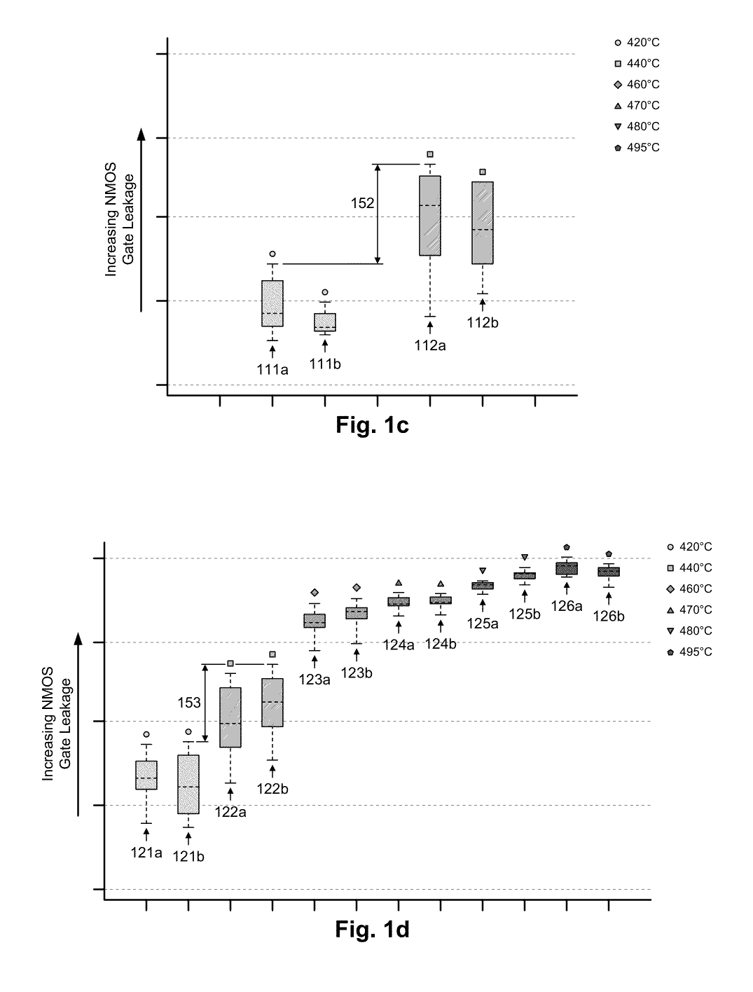

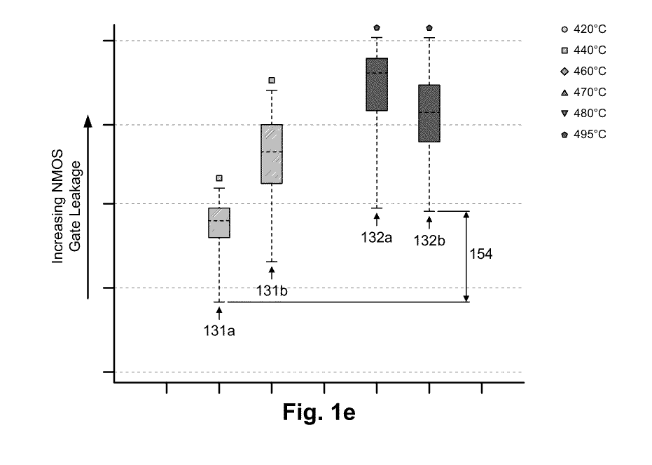

In certain exemplary embodiments, reducing the replacement gate fill material deposition process from the elevated temperatures that are commonly used in prior art HK/MG transistor devices, e.g., 450-500° C., down to approximately 420° C. has been shown to result in an unanticipated degree of enhancement of the overall performance of some semiconductor devices. For example, FIGS. 1a and 1b illustrate the relative performance improvement of at least some representative PMOS high-k/metal gate transistor devices based on one device evaluation metric, wherein the ratio of the drive-current (Iₒₙ) vs. the threshold voltage (V_{T}) of some PMOS transistors was measured after using different replacement gate fill material deposition temperatures. More specifically, FIG. 1a is a data plot showing the Iₒₙ and V_{T} parameters of a plurality of HK/MG PMOS transistor elements that were formed using a conductive metal fill deposition temperature of approximately 495° C., and FIG. 1b is a similar data plot showing the same evaluation parameters of a plurality of substantially similar PMOS devices, wherein however the devices were formed using a fill material deposition temperature of approximately 440° C.

FIG. 1a shows a cluster of relevant data points 101 based on the 495° C. fill deposition temperature, and FIG. 1b shows a cluster of relevant data points 102 based on the 440° C. fill deposition temperature. The data cluster 102 shows an upward (increasing) shift 151 in drive current (Iₒₙ) that equates to approximately a 10% increase relative to that of the data cluster 101. The data cluster 102 also shows a rightward (increasing) shift in threshold voltage (V_{T}) of a similar magnitude. The relative shifts in these two device parameters illustrates a potentially substantial impact on the overall improvement of PMOS devices that may be formed using lower fill deposition temperatures.

In another device evaluation metric, the leakage current of a plurality of representative high-k/metal gate NMOS transistor devices was measured based on various device configurations and metal fill deposition temperatures, as illustrated in FIGS. 1c-1e. For example, FIG. 1c depicts gate leakage data 111a, 111b that was measured on a plurality of representative HK/MG NMOS transistors that were formed using a conductive metal fill deposition temperature of approximately 420° C. Similarly, gate leakage data 112a, 112b was measured for a plurality of substantially similar NMOS devices, wherein however the conductive metal fill process was performed at a temperature of approximately 440° C. As shown in FIG. 1c, the gate leakage data 111a, 111b based on a 420° C. fill temperature is less than the corresponding gate leakage data 112a, 112b based on a 440° C. fill temperature by an amount 152 that equates to a relative NMOS gate leakage difference of approximately 10×, i.e., about one order of magnitude.

FIG. 1d illustrates gate leakage data that was measured for a plurality of representative HK/MG NMOS devices similar to those shown in FIG. 1c, wherein however the NMOS devices were formed using fill deposition process that extend over a wider range of temperatures. The test data shown in FIG. 1d, however, was obtained using NMOS devices having a slightly thicker gate dielectric layer, i.e., by approximately 3-5 Å, than the gate dielectric layer of the representative NMOS devices used to obtain the data shown in FIG. 1c, e.g., a 12-14 Å thick gate insulation layer. The gate dielectric layer thickness parameter for the representative NMOS devices of FIG. 1d was increases as noted so as to be able to obtain meaningful leakage data for those devices formed using a metal fill deposition process in excess of approximately 440° C.

To obtain the gate leakage data illustrated in FIG. 1d, a variety of gate leakage tests were performed on NMOS devices that were formed using the following metal fill deposition temperatures:

| Fill | |
|---|---|
| Temperature | Test(s) |
| 420° C. | 121a, 121b |
| 440° C. | 122a, 122b |
| 460° C. | 123a, 123b |
| 470° C. | 124a, 124b |
| 480° C. | 125a, 125b |
| 495° C. | 126a, 126b |

As with relative gate leakage data presented in FIG. 1c above, the gate leakage data 121a, 121b shown in FIG. 1d (based on the 420° C. fill temperature) is less than the corresponding gate leakage data 122a, 122b (based on the 440° C. fill temperature) by an amount 153 that also equates to a relative NMOS gate leakage reduction of approximately 10×, i.e., about one order of magnitude. Furthermore, the data present in FIG. 1d shows that the gate leakage of devices formed using deposition temperatures from 460-495° C. are even higher.

FIG. 1e presents further relative gate leakage data for additional representative NMOS transistor devices formed using different metal fill deposition temperatures. More specifically, the gate leakage 131a, 131b was measured for a plurality of representative HK/MG NMOS transistors formed using a metal fill deposition temperature of approximately 440° C., whereas the gate leakage data 132a, 132b was measured for a plurality of substantially similar NMOS devices formed using a fill temperature of approximately 495° C. As shown in FIG. 1e, the gate leakage data 131a, 131b based on a 440° C. fill temperature is less than the corresponding gate leakage data 132a, 132b based a 495° C. fill temperature by an amount 154 that equates to a relative NMOS gate leakage difference of approximately 10×, or again approximately a one order of magnitude difference.

Accordingly, as the above-described FIGS. 1a-1e show, a surprisingly significant and unexpected increase in overall transistor device performance may be realized when only a relatively minor temperature reduction, such as 30-40° C. or even less, is made during device processing, i.e., the conductive metal fill deposition temperature.

As may be further appreciated by those of ordinary skill having full benefit of the present disclosure, in those illustrative embodiments wherein the work-function material layers may be formed having a residual stress level so as to improve the overall mobility of holes and/or electrons in the channel region of a given device, the lower deposition temperatures noted above may also tend to have a reduced effect from a stress-relaxation viewpoint on the residual stress levels of the work-function material layers. In such cases, the overall improvement in device performance that may be associated with enhanced levels of residual stress may be substantially maintained at a relatively higher level, as compared to the prior art processing methods and temperatures that may result in some measure of stress relaxation and the associated reduction in charge carrier mobility.

Depending on the relative amount of germanium present in an aluminum-germanium metal alloy, the temperature at which the AlGe alloy is able to sufficiently “flow” so as to provide a substantially void-free conductive metal fill in a replacement metal gate electrode may be reduced. For example, as the germanium content of the AlGe alloy approaches approximately 5% by weight, the deposition temperature at which the AlGe alloy is able to readily “flow” and fill a gate cavity may be lowered to approximately 420° C., or even lower, thereby providing at least some of the above-described performance enhancement benefits that may be associated with an overall reduced device thermal budget. Furthermore, the presence of germanium in the AlGe alloy may also tend to stimulate a larger grain size growth during the deposition process, thereby providing enhanced electrical performance by increasing material conductivity, as previously described.

In other illustrative embodiments of the present disclosure, a conductive metal fill material may be formed in a replacement metal gate electrode by performing an electrochemical deposition process at a temperature below approximately 50° C., whereas in some embodiments, the electrochemical deposition process may be performed below approximately 35° C. In certain embodiments, the electrochemical deposition process may be, for example, an electroless deposition process. Furthermore, in at least some illustrative embodiments the conductive metal fill material may be, for example, a cobalt-tungsten-phosphorous (CoWP) alloy fill material, whereas in other embodiments, the conductive metal fill may be one of nickel (Ni), palladium (Pd), gold (Au), silver (Ag), or alloys thereof.

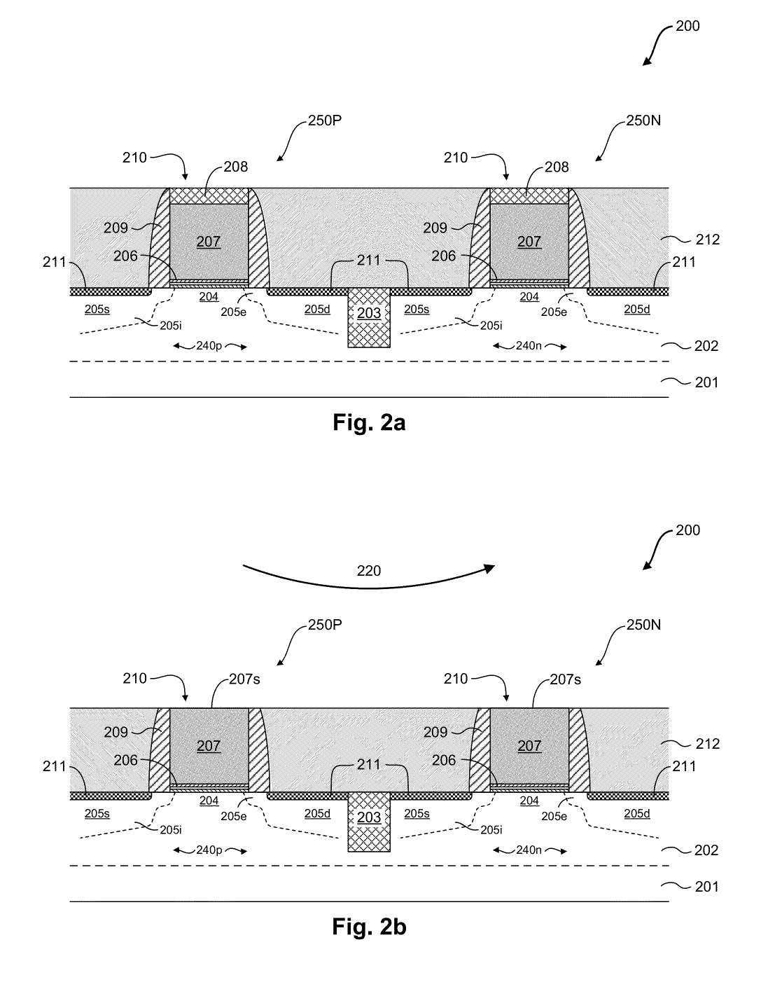

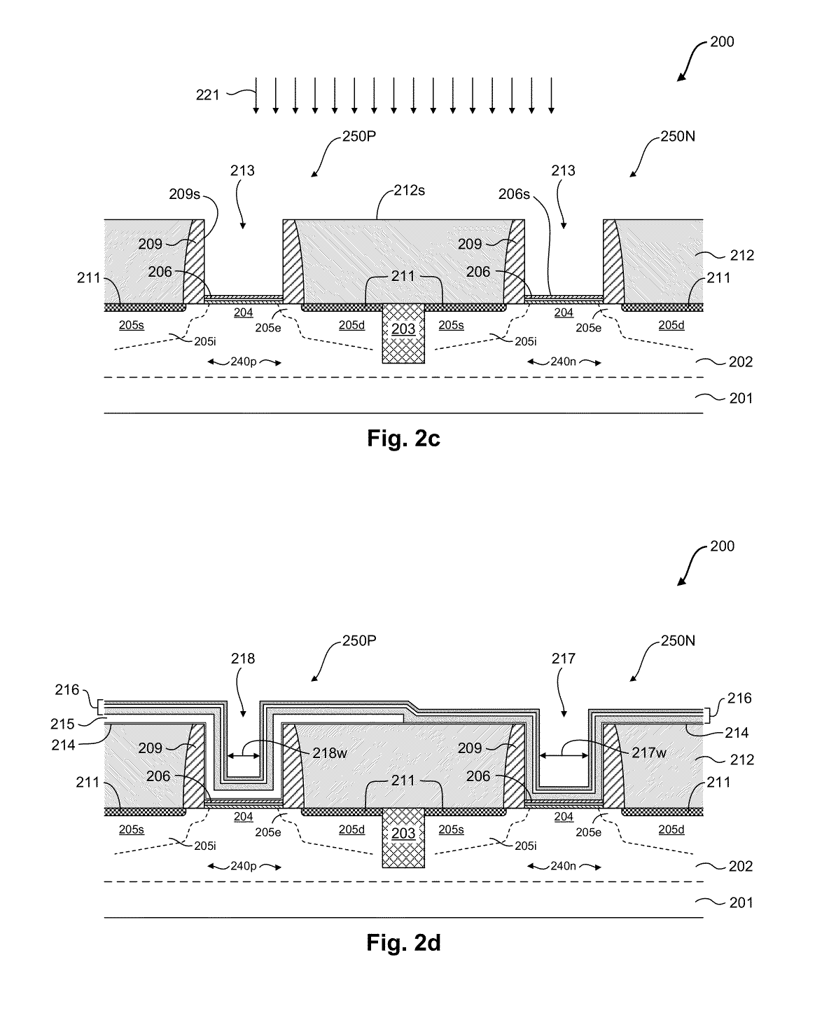

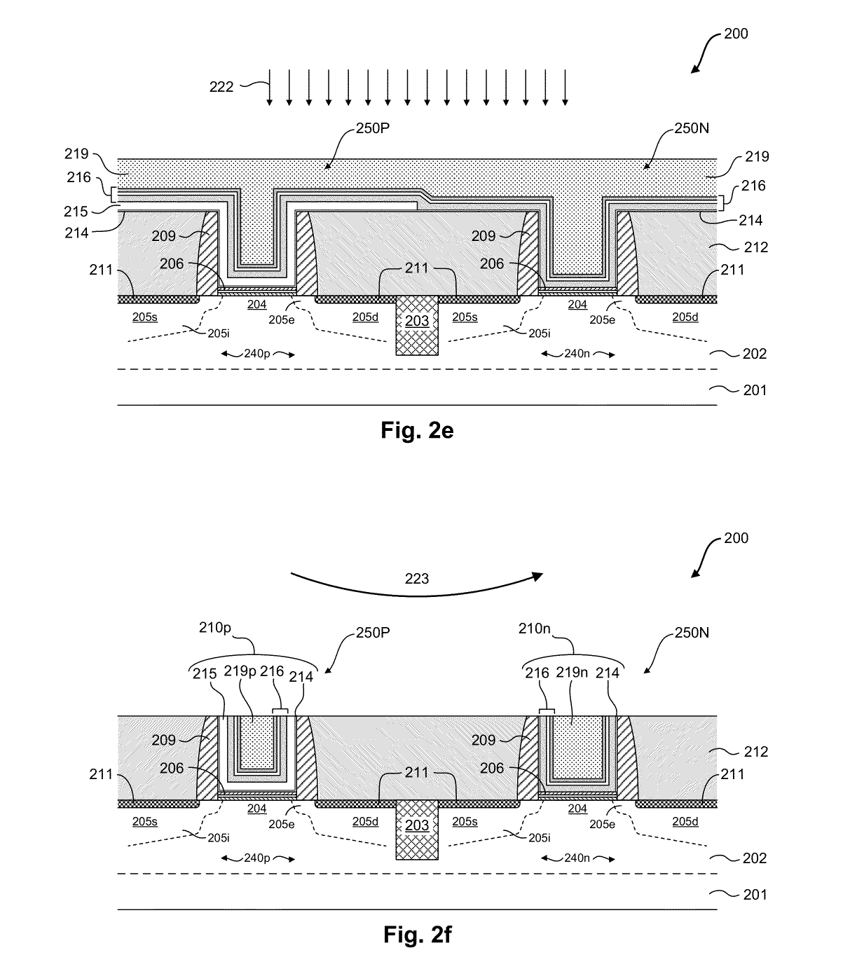

With respect to the descriptions of the various illustrative embodiments set forth herein, it should be understood that, unless otherwise specifically indicated, any relative positional or directional terms that may be used in the descriptions below—such as “upper,” “lower,” “on,” “adjacent to,” “above,” “below,” “over,” “under,” “top,” “bottom,” “vertical,” “horizontal,” and the like—should be construed in light of that term's normal and everyday meaning relative to the depiction of the components or elements in the referenced figures. For example, referring to the schematic cross-section of the semiconductor device 200 depicted in FIG. 2a, it should be understood that the gate structures 210 are formed “above” the semiconductor layer 202, and that the substrate 201 is positioned “below” or “under” the semiconductor layer 202. Similarly, it should also be appreciated that the spacer structure 209 is positioned “adjacent to” the sidewalls of the gate structures 210, whereas in special cases, the spacer structure 209 may be positioned “on” the sidewalls of the gate structures 210 in those configurations where no layers or structures are interposed therebetween.

FIGS. 2a-2f shows various steps in one illustrative method of forming transistor devices having a material region made up of an alternative semiconductor material in the channel regions of the devices. FIG. 2a schematically depicts a cross-sectional view of an illustrative semiconductor device 200 during an intermediate manufacturing stage of a replacement metal gate (RMG) technique. In certain embodiments, the semiconductor device 200 may be based on CMOS device architecture, in which case the device 200 may include, among other things, an NMOS transistor 250N and a PMOS transistor 250P, both of which may be formed in and above a semiconductor layer 202 of a substrate 201. Depending on the overall device requirements, the semiconductor layer 202 may be substantially silicon, or it may be a silicon-based material layer. Additionally, the semiconductor layer 202 may be separated into active areas 240n and 240p by an isolation structure, such as the shallow isolation structure 203 shown in FIG. 2a, wherein each of the active areas 240n and 240p may include an appropriate dopant species as may be necessary for establishing the requisite conductivity type for the transistor elements 250N and 250P, respectively. Furthermore, in some embodiments, the semiconductor layer 202 may be formed on, or be a part of, a substantially crystalline substrate material, whereas in other embodiments, some or all of the device regions making up the semiconductor device 200 may be formed on the basis of a silicon-on-insulator (SOI) architecture, in which case a buried insulation layer (not shown) may be provided below the semiconductor layer 202.

In certain embodiments of the present disclosure, such as is illustrated in FIGS. 2a-2f, the replacement gate integration scheme used to form the high-k dielectric/metal gate electrode (HK/MG) transistor elements 250N, 250P may be based on a so-called “hybrid” replacement gate processing technique. In the hybrid replacement gate technique, a sacrificial gate stack is formed above the semiconductor layer 202 that may include, among other things, the requisite high-k gate dielectric material that will eventually be used to form the finished transistor elements 250N and 250P. The sacrificial gate stack may also include a polysilicon or amorphous silicon material layer that is formed above the high-k gate dielectric material, which in some embodiments may be followed by a dielectric cap layer so as to facilitate patterning and/or etching activities. Thereafter, a patterning process may be performed so as to form a sacrificial gate structure, such as the sacrificial gate structures 210 shown in FIG. 2a. During later manufacturing stages of the hybrid replacement gate technique, the polysilicon or amorphous silicon material, sometimes referred to as a “dummy” gate electrode, may then be selectively removed from the sacrificial gate structure such that the high-k gate dielectric material is left in place. Thereafter, the requisite N-metal and/or P-metal work-function material layers of an appropriately designed replacement metal gate electrode may be formed above the high-k gate dielectric material, as will be described in further detail below.

In other embodiments of the present disclosure, the replacement gate integration scheme used to form the HK/MG transistor elements 250N, 250P may be a so-called “full” replacement gate processing technique. In the full replacement gate technique, device processing is similar to that described with respect to the hybrid technique above, except that the entire sacrificial gate structure may be based on a traditional polySiON gate architecture configuration, i.e., wherein the gate dielectric material is also a “dummy” structure. The “dummy” gate dielectric material is then removed along with the “dummy” gate electrode prior to forming the HK/MG replacement gate structure, which is formed to include the requisite high-k gate dielectric material. It should therefore be appreciated that, while FIGS. 2a-2f depict at least some of the processing steps that may be used in the hybrid replacement gate technique, these figures are illustrative only, and either replacement gate approach, e.g., “hybrid” or “full,” may be utilized within the spirit and scope of the present disclosure.

As shown in illustrative embodiment depicted in FIG. 2a, each of the transistor elements 250N, 250P may be made up of a sacrificial gate structure 210. In some embodiments, each sacrificial gate structure 210 may include a high-k gate dielectric material 206 formed above a channel region 204 in a respective active area 240n, 240p of the semiconductor layer 202, as well a “dummy” gate electrode 207 formed above the high-k gate dielectric material 206. In certain illustrative embodiments, the high-k gate dielectric material 206 may be made up of one material layer or a plurality of material layers, depending on the specific device requirements. For example, in some transistor element designs, the high-k gate dielectric material 206 may include one or more materials having a dielectric constant “k” that is approximately 10 or greater, such as tantalum oxide (Ta₂O₅), strontium titanium oxide (SrTiO₃), hafnium oxide (HfO₂), zirconium oxide (ZrO₂), titanium oxide (TiO₂), aluminum oxide (Al₂O₃), yttrium oxide (Y₂O₃), lanthanum oxide (La₂O₅), hafnium silicates (HfSiOₓ), hafnium silicon oxynitrides (HfSiOₓN_{y}), and the like. Furthermore, it should be appreciated that, in at least some embodiments, the specific high-k material or materials making up the high-k gate dielectric materials 206 may be different for the NMOS and PMOS transistor elements 250N, 250P. Moreover, in those embodiments of the present disclosure wherein the gate dielectric material 206 is a “dummy” gate dielectric layer, such as when an integration scheme based on a “full” replacement gate technique is used, the gate dielectric material 206 may also be, for example, a silicon dioxide or silicon oxynitride material, and the like.

In certain embodiments, e.g., based on the hybrid replacement gate technique, the dummy gate electrodes 207 of the sacrificial gate structures 210 may be, for example an amorphous silicon or polysilicon material. Furthermore, as shown in FIG. 2a, either or both of the sacrificial gate structures 210 may include a dielectric cap layer 208 formed above the dummy gate electrode 207. In some embodiments, the dielectric cap layer 208 may be used as a hard mask during some device processing steps, and may be made up of a suitable dielectric material, such as silicon nitride and the like. In other embodiments, sidewall spacer structures 209 may be formed on or adjacent to one or both of the sacrificial gate structures 210. Additionally, depending on the overall device processing requirements, the sidewall spacer structures 209 may be single spacer elements that are made up of, for example, silicon nitride and the like. In other embodiments, the sidewall spacer structures 209 may include a plurality of selectively etchable spacer elements, such as a liner/offset spacer and/or other sidewall spacers (not shown), which may comprise, for example, silicon dioxide and silicon nitride, respectively. Furthermore, it should be appreciate that the spacer structures 209 may be used as implantation masks when forming the source and drain regions 205s, 205d in the respective active areas 240n, 240p of the semiconductor layer 202, based on implantation techniques and sequences well known in the art. For example, the source and drain regions 205s, 205d may be made up of shallow implantation extension regions 205e, as well as deep implantation regions 205i, as are schematically illustrated in FIG. 2a.

In certain embodiments, metal silicide regions 211 may also be formed in the respective contact regions of the active areas 240n, 240p, e.g., in the source and drain regions 205s, 205d adjacent to the spacer structures 209 of the transistor elements 250N, 250P, respectively. Furthermore, as shown in FIG. 2a, an interlayer dielectric material 212, such as a silicon dioxide material and the like, may be formed above the active areas 240n, 240p and around the sacrificial gate structures 210, thereby electrically isolating the transistor elements 250N and 250P.

FIG. 2b schematically illustrates the semiconductor device 200 of FIG. 2a in a further manufacturing stage of the illustrative replacement gate integration, wherein a planarization process 220, such as a chemical mechanical polishing (CMP) process and the like, may be performed so as to remove an upper portion of the interlayer dielectric material 212, as well as an upper portion of the sacrificial gate structures 210. As shown in FIG. 2b, the cap layers 208 may be completely removed from the sacrificial gate structures 210 during the planarization process 220, thereby exposing an upper surface 207s of the material of the dummy gate electrode 207. Thereafter, as shown in FIG. 2c, an etch process 221 may be performed so as to selectively remove the dummy gate electrodes 207 from each of the sacrificial gate structures 210, relative to the sidewall spacer structures 209 and the interlayer dielectric material 212, thereby forming a gate cavity 213 in each of the NMOS and PMOS transistor elements 250N, 250P. Accordingly, in at least some embodiments, the sidewalls of the gate cavities 213 may be the inner surfaces 209s of the spacer structures 209, as shown in FIG. 2c. Depending on the specific process flow requirements, the etch process 221 may include, for example, a suitably designed isotropic etch process, recipes for which are well known in the art, such as a hydrofluoric/nitric acid (HF/HNO₃) solution, and the like. Other etch processes may also be used.

In certain embodiments of the present disclosure, e.g., such as when a hybrid replacement gate technique is employed, the high-k gate dielectric material 206 may include an upper material layer that may be used as an etch stop during the etch process 221, thereby reliably stopping the etch process 221 after the gate cavities 213 have been formed in the sacrificial gate structures 210. Accordingly, in, for example, the hybrid replacement gate technique, the high-k gate dielectric material 206 may be left in place, and an upper surface 206s may be exposed in preparation for forming the various requisite N-metal and/or P-metal work-function material layers thereabove, as will be described briefly below.

FIG. 2d depicts the semiconductor device 200 illustrated in FIG. 2c after several subsequent manufacturing steps of the illustrative replacement gate technique have been performed, wherein respective N-metal and P-metal work-function materials have been formed in the gate cavities 213 (see, FIG. 2c) and above the interlayer dielectric material 212 using conventional semiconductor processing techniques well known in the art. In the illustrative embodiment shown in FIG. 2d, a P-metal work-function material 215 has been deposited above the PMOS transistor element 250P, such that the P-metal work-function material 215 is formed in the PMOS gate cavity 213 as well as above an upper surface 212s the interlayer dielectric material 212 (see, FIG. 2c). Depending on the device requirements, the P-metal work-function material 215 may be made up of one or more layers of any one of a variety of metal gate electrode materials well known to those having ordinary skill in the art. For example, the P-metal work-function material 215 may include one or more materials such as titanium nitride (TiN), titanium oxynitride (TiON), titanium oxycarbide (TiOC), titanium (T), aluminum (Al), tantalum (Ta), tantalum nitride (TaN), platinum (Pt), rubidium (Ru), iridium (Ir) and the like. It should be understood, however, that above abbreviated listed of exemplary metal gate electrode materials does not in any way limit the specific materials and/or material combinations that may be used for the P-metal work-function material 215.

Also as shown in FIG. 2d, an N-metal work-function material 216 may be formed above the NMOS transistor element 250N, i.e., in the NMOS gate cavity 213 and above the upper surface 212s of the interlayer dielectric material 212. Furthermore, in at least some illustrative embodiments, the N-metal work-function material 216 may also be formed above the PMOS transistor element 250P—that is, in the PMOS gate cavity 213 and above the interlayer dielectric material 212, so as to thereby cover the previously-formed P-metal work-function material 215. In certain embodiments, the N-metal work-function material 216 may be made up of plurality of material layers comprising one or more metal gate electrode materials, such as, for example, titanium nitride (TiN), titanium (Ti), aluminum (Al), tantalum carbide (TaC) and the like. Other materials and/or material combinations may also be used, depending on the overall device design requirements.

Furthermore, in certain embodiments of the present disclosure, the N-metal work-function material 216 may also include a final blocking layer, such as, for example, a tantalum nitride material layer and the like. In at least some embodiments, the final blocking layer may act to substantially prevent any aluminum that may be present in a subsequently formed conductive metal fill material, e.g., the conductive metal fill material 219 of FIG. 2e (described below), from diffusing toward the channel region 204 of the PMOS transistor element 250P, thus also substantially preventing an undesirable modulation of the work function of the PMOS transistor element 250P, and/or gate leakage, in an uncontrolled manner. Furthermore, as may be appreciated by those of ordinary skill having the full benefit of the subject matter disclosed herein, such undesirable diffusion of aluminum may also be substantially reduced by the lower deposition temperatures that may be used to form the conductive metal fill material 219, e.g., the deposition process 222 of FIG. 2e, in accordance with the present disclosure.

In at least some embodiments, one or more of the metal gate electrode material layers making up the P-metal and/or N-metal work-function materials 215, 216, respectively, may be formed in the gate cavities 213 and above the high-k gate dielectric materials 206 with a residual intrinsic stress that may be adapted to have a beneficial influence on the strain in the channel regions 204 of the respective transistor devices 250P, 250N. For example, the deposition parameters used to form one or more of the layers comprising the N-metal work-function material 216 may be adjusted so as to induce a tensile strain in the channel region 204 of the NMOS transistor element 250N, thereby potentially increasing the mobility of electrons in the channel 204. Similarly, the deposition parameters used to form the P-metal work-function material 215 may also be adjusted so as to induce a compressive strain in the channel region 204 of the PMOS transistor element 250P, which could also act to increase hole mobility in the channel region 204.

Depending on the device processing requirements, an etch stop layer 214, such as a tantalum nitride material layer, and the like, may be formed above both the NMOS and PMOS transistor elements 250N and 250P prior to forming the P-metal and N-metal work-function materials 215 and 216, respectively, above the semiconductor device 200. In certain embodiments, the etch stop layer 214 may be used during a selective etch step (not shown) that is adapted to selectively remove the P-metal work-function material 215 from inside the NMOS gate cavity 213 prior to forming the N-metal work-function material 216. In at least some embodiments, a patterned etch mask (not shown) may be formed above the PMOS transistor element 250P during the above-noted selective etch step so as to protect the PMOS transistor element while the P-metal work-function material 215 is being removed from above the NMOS transistor 250N.

In other exemplary embodiments of the present disclosure (not shown in FIG. 2d), the processing scheme described above may be substantially reversed, i.e., wherein the N-metal work-function material 216 is formed above the semiconductor device 200, e.g., inside of both gate cavities 213, prior to forming the P-metal work-function material 215. In such illustrative embodiments, the etch stop layer 214 and an appropriately patterned etch mask (not shown) may be used to selectively remove the N-metal work-function material 216 from inside the PMOS gate cavity 213, after which the P-metal work-function material may be formed above both transistor elements 250N, 250P.

As shown in FIG. 2d, after the work-function materials 215 and 216 have been formed above the semiconductor device 200, only a portion of the gate cavities 213 (see, FIG. 2c) remain unfilled. For example, after the N-metal work-function material 216 has been formed above NMOS transistor element 250N, a reduced-size NMOS gate cavity 217 having a gap width 217w remains. In some embodiments, the gap width 217w may range on the order of approximately 14-16 nm, although, depending on the original gate length of the NMOS transistor 250N and the thickness of the N-metal work-function material 216, the gap width 217w may be either larger or smaller. Similarly, a reduced-size PMOS gate cavity 218 having a gap width 218w also remains, however the gap width 218w is typically approximately 4-6 nm narrower than the gap width 217s, size both the P-metal and N-metal work-function materials 215 and 216 may have been formed above PMOS transistor element 250P. For example, in certain illustrative embodiments, the gap width 218w may be approximately 10-12 nm, although, as with the NMOS gate cavity 217, the gap width may be either larger or smaller, depending on the thicknesses of the work-function materials 215 and 216. However, it should be appreciated after a complete reading of the present disclosure that the subject matter described herein is not limited to only those gate cavities that may have a reduced-size gap width, such as the illustrative gap widths 218w and 217w shown in FIG. 2d.

FIG. 2e schematically illustrates the semiconductor device 200 of FIG. 2d in a further manufacturing stage, wherein a conductive metal fill material 219 has been formed above the device 200 so as to substantially fill the NMOS and PMOS gate cavities 217 and 218, respectively. In some embodiments, the conductive metal fill material 219 may be formed in and above the gate cavities 217, 218 by performing a deposition process 222 at a reduced temperature relative to the conventional prior art processes described above so as to potentially avoid, or at least reduce, an uncontrolled and unwanted shift in the work function of the NMOS and/or PMOS transistor elements 250N, 250P. Furthermore, in certain embodiments, due to the reduced deposition temperature of the deposition process 222, any residual intrinsic stresses that may be present in the work-function material layers 215 and/or 216 may not be affected, or alternatively may only be relaxed to a comparatively lesser degree, relative to the elevated temperatures used in conventional prior art processes.

In one exemplary embodiment, the deposition process 222 may be a reduced temperature PVD process, which may be performed at a temperature below approximately 450° C. In yet another illustrative embodiment, the reduced temperature PVD deposition process 222 may be performed at a temperature less than approximately 420° C., whereas in other embodiments, the deposition process 222 may be performed at less than approximately 400° C. Additionally, in at least some illustrative embodiments, the reduced temperature deposition process 222 may be used to deposit a conductive metal fill material 219 into the NMOS and PMOS gate cavities 217 and 218 that is made up of, for example, an aluminum-germanium material alloy. Furthermore, in certain embodiments the germanium content of the aluminum-germanium conductive metal fill material 219 may be adjusted so that fill material 219 can more readily “flow” into the gate cavities 217 and 218, thereby substantially reducing the likelihood that voids may be created in the gate cavities 217, 218. Moreover, the germanium content of the aluminum-germanium conductive metal fill material 219 may be further adjusted so as to promote larger grain size growth during the deposition process 222. For example, in at least some illustrative embodiments, the germanium content of the aluminum-germanium conductive metal fill material 219 may be up to approximately 5% by atomic weight, although other germanium concentrations may also be used.

In another exemplary embodiment disclosed herein, the deposition process 222 may be an electrochemical deposition process, wherein the semiconductor device 200 may be exposed to an appropriately designed chemical solution containing, among other things, the desired material and/or materials to be deposited above the device 200. Depending on the desired processing parameters, such as, the material type and/or the make-up of the chemical solution and the like, the electrochemical deposition process 222 may be performed at a temperature less than approximately 50° C., whereas in at least one embodiment the electrochemical deposition process 222 may be performed in a temperature range of approximately 30-35° C. Accordingly, the benefits associated with the reduced-temperature PVD process described above may also accrue to the finished HK/MG transistor elements 250N and 250P by use of the electrochemical deposition process 222, due at least in part to the substantially reduced deposition temperature as compared to the conventional prior art processes, and the consequently decreased thermal budget of the semiconductor device 200.

In certain embodiments, the electrochemical deposition process 222 may be, for example, an electroless plating process, which may be performed without the benefit of an external electrical power source. Depending on the specific device parameters, the electroless plating process 222 may be used to form a suitable conductive metal fill material 219 inside of each of the gate cavities 217, 218, such as, for example, a cobalt-tungsten-phosphorous metal alloy, and the like. In some embodiments, the electroless plating process 222 may be used to deposit other conductive metals, such as nickel, palladium, gold, and/or alloys thereof. Other suitable conductive metal fill materials 219 may also be used, depending on the overall device design and process requirements.

In other illustrative embodiments, the electrochemical deposition process 222 may be, for example, an electroplating process, wherein an external electrical power source is used to facilitate material deposition. In certain embodiments, a conductive seed layer (not shown) may be deposited above the semiconductor device 200 and so as to enable the electroplating process 222 to deposit material on the surfaces to be plated. Furthermore, in at least some embodiments, the final layer and/or layers of the work-function material 215 or 216 may act as an appropriate seed layer, provided those final layers have sufficient conductivity to enable the electroplating operation to take place. Additionally, it should be appreciated that when an electroplating process 222 is used to form the conductive metal fill material 219 above the semiconductor device 200, the fill material 219 may be any one or more of the previously described materials that may also be used when performing an electroless plating process.

FIG. 2f schematically illustrates the semiconductor device 200 of FIG. 2e in a further manufacturing stage, after a planarization process 223, such as a CMP process and the like, has been formed to remove any excess portions of the etch stop layer 214 (when used), the work-function materials 215, 216, and the conductive metal fill material 219 from above the interlayer dielectric material 212. As shown in FIG. 2f, after completion of the planarization process 223, the NMOS transistor element 250N may include a replacement metal gate electrode 210n, which may be made up of, among other things, the etch stop material 214 (when used), the N-metal work-function material 216, and the conductive metal fill 219n. Similarly, a replacement metal gate electrode 210p, which may include the etch stop material 214 (when used), the P-metal work-function material 215, the N-metal work-function material 216, and a conductive metal fill 219p, may now be part of the PMOS transistor element 250P. Thereafter, further device processing may continue based on conventional techniques well known in the art so as to form contact elements (not shown) through the interlayer dielectric material 212 to the metal silicide regions 211, and metallization layers (not shown) containing conductive lines and vias thereabove so as to form the various components of the electrical circuit layout (not shown) of the semiconductor device 200.

As a result of the presently disclosed subject matter, semiconductor device processing methods are described wherein a reduced temperature material deposition process, such as a reduced temperature PVD process and/or electrochemical deposition process, may be used to deposit a conductive metal fill material above N-metal and/or P-metal work-function material layers when forming HK/MG replacement gate electrodes. In certain embodiments, the reduced temperature material deposition may be performed at less than approximately 450° C. so as reduce the likelihood that an uncontrolled transistor element work function shift may occur, as compared to device processing that may be performed based on a higher thermal budget, e.g., with a higher conductive metal fill material deposition process. Furthermore, the methods disclosed herein may also reduce the likelihood that an otherwise detrimental stress-relaxation may occur to any material layers that may have been formed with a high intrinsic internal stress level during device processing, thereby substantially maintaining the beneficial effect that these stressed material layers may have on charge carrier mobility in the respective channel regions of NMOS and/or PMOS transistor devices.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

1. A method, comprising:
forming a sacrificial gate structure above a semiconductor layer, said sacrificial gate structure comprising a dummy gate electrode;
forming a gate cavity by removing at least said dummy gate electrode from above said semiconductor layer;
forming a work-function material of a replacement metal gate electrode in said gate cavity; and
forming a conductive metal fill material in said gate cavity and above said work-function material, wherein forming said conductive metal fill material comprises performing a physical vapor deposition process at a temperature below approximately 450° C.

2. The method of claim 1, wherein forming said conductive metal fill material comprises performing said physical vapor deposition process at a temperature below approximately 420° C.

3. The method of claim 1, wherein forming said conductive metal fill material comprises performing said physical vapor deposition process at a temperature below approximately 400° C.

4. (canceled)

5. The method of claim 1, wherein forming said conductive metal fill material comprises forming an aluminum-germanium material alloy in said gate cavity and above said work-function material.

6. The method of claim 5, wherein forming said aluminum-germanium material alloy comprises forming said aluminum-germanium material alloy with a germanium content of approximately 5% atomic weight or less.

7.-12. (canceled)

13. The method of claim 1, wherein said sacrificial gate structure further comprises a dummy gate dielectric layer, and wherein forming said gate cavity further comprises removing said dummy gate dielectric layer from above said semiconductor layer.

14. The method of claim 1, wherein forming said work-function material comprises forming at least one material layer having an intrinsic internal stress.

15. A method for forming a replacement gate structure of a semiconductor device, the method comprising:
forming a sacrificial gate structure above a semiconductor layer of said semiconductor device;
forming a gate cavity by selectively removing said sacrificial gate structure from above said semiconductor layer;
partially filling said gate cavity by forming at least one layer of a metal gate electrode work-function material in said gate cavity; and
filling a remaining portion of said gate cavity with a conductive metal fill material by performing a physical vapor deposition process at a temperature below approximately 450° C.

16. The method of claim 15, wherein said physical vapor deposition process is performed at a temperature in the range of approximately 400-420° C.

17. The method of claim 15, wherein said physical vapor deposition process is performed at a temperature below approximately 400° C.

18. The method of claim 15, wherein filling a remaining portion of said gate cavity with said conductive metal fill material comprises depositing an aluminum-germanium material alloy having a germanium content of less than approximately 5% atomic weight inside said remaining portion of said gate cavity and above said at least one layer of metal gate electrode work-function material.

19. The method of claim 15, wherein forming said at least one layer of metal gate electrode work-function comprising forming said at least one layer of metal gate electrode work-function material with an intrinsic internal stress level.

20.-22. (canceled)

23. A method for forming a replacement gate structure of a semiconductor device, the method comprising:
forming a sacrificial gate structure above a semiconductor layer of said semiconductor device;
forming a gate cavity by selectively removing said sacrificial gate structure from above said semiconductor layer;
partially filling said gate cavity by forming at least one layer of a metal gate electrode work-function material having an intrinsic internal stress level in said gate cavity; and
performing a physical vapor deposition process at a temperature below approximately 450° C. to fill a remaining portion of said gate cavity with a conductive metal fill material by depositing an aluminum-germanium material alloy having a germanium content of less than approximately 5% atomic weight above said at least one layer of metal gate electrode work-function material.

24. The method of claim 15, wherein said physical vapor deposition process is performed at a temperature in the range of approximately 400-420° C.

25. The method of claim 15, wherein said physical vapor deposition process is performed at a temperature below approximately 400° C.
